(19) United States
(12) Patent Application Publication
(10) Pub. No.: US 2014/0021537 A1
(43) Pub. Date: Jan. 23, 2014

(54) SEMICONDUCTOR DEVICE AND METHOD FOR MANUFACTURING THE SAME

(71) Applicant: SK HYNIX INC., Icheon-si (KR)

(72) Inventors: Seung Hwan KIM, Seoul (KR); Jai Hoon SIM, Seongnam-si (KR)

(73) Assignee: SK HYNIX INC., Icheon-si (KR)

(21) Appl. No.: 13/846,884

(22) Filed: Mar. 18, 2013

(30) Foreign Application Priority Data
Jul. 23, 2012 (KR) 10-2012-0080207

(51) Int. Cl. H01L 29/423

(52) U.S. Cl. CPC H01L 29/42356
USPC 257/330

(57) ABSTRACT

A semiconductor device and a method for forming the same includes a pillar formed over a semiconductor substrate, a buried bit line formed below the semiconductor substrate, a vertical gate formed over a sidewall of the pillar, an insulation film pattern formed to expose one side of the vertical gate disposed between the pillars, and a word line coupled to the exposed vertical gate. The vertical gate is formed to cover a portion of a sidewall of the pillar with a metal material, a word line overlaps with some parts of the vertical gate, and some parts of the pillar are shifted to be coupled to the vertical gate.

### CROSS-REFERENCE TO RELATED APPLICATION

The priority of Korean patent application No. 10-2012-0080207 filed on 23 Jul. 2012, the disclosure of which is hereby incorporated in its entirety by reference, is claimed.

### BACKGROUND OF THE INVENTION

Embodiments of the present invention relate to a semiconductor device including a vertical gate and a method for forming the same. Under a configuration of a vertical gate according to an embodiment of the present invention, noise caused by a neighboring word line is reduced and resistance of the word line is improved.

Generally, a semiconductor is a material that can be a conductor or an insulator. Although a semiconductor is similar to an insulator in a pure state, electrical conductivity of a semiconductor can be increased by impurity implantation or other manipulation. A semiconductor device has various functions and is formed of a semiconducting element. A representative example of a semiconductor device is a semiconductor memory device.

A semiconductor memory device includes a plurality of memory cells each having a capacitor and a transistor. The capacitor is used to temporarily store data, and the transistor is used to transfer data between a bit line and the capacitor in response to a control signal (word line). The data transfer occurs using a semiconductor property whereby electrical conductivity changes depending on environmental conditions. A transistor has three regions, i.e., a gate, a source, and a drain. Electric charges are moved between the source and the drain according to a control signal input to the gate of the transistor. The charges between the source and the drain move through a channel region in accordance with the properties and operation of the semiconductor device.

In a typical method for manufacturing a transistor, a gate is formed in a semiconductor substrate, and a source and a drain are formed by doping impurities into both sides of the gate. In this case, a channel region of the transistor is defined between the source and the drain under the gate. A transistor having a horizontal channel region occupies a predetermined area of a semiconductor substrate. Therefore, for a given transistor, the number of memory cells including such a transistor may determine the size of the semiconductor device.

If the total area of a semiconductor memory device is reduced, the number of semiconductor memory devices per wafer is increased, thereby improving productivity. Several methods for reducing the total area of a semiconductor memory device have been proposed. One method is to replace a conventional planar transistor having a horizontal channel region with a vertical transistor having a vertical channel region.

If the vertical transistor is used in a memory cell in the semiconductor device, the size of the memory cell can be reduced to 4F2, where F is a minimum distance between patterns according to a specific design rule. If a vertical transistor is used as a cell transistor, a capacitor is coupled to the upper part of the vertical transistor and a bit line coupled to the lower part of the vertical transistor is buried in the semiconductor substrate. In this case, the word line coupled to a gate of the cell transistor is formed to enclose a vertical pillar over the bit line.

However, such a vertical transistor is susceptible to an electrical short-circuit between the buried bit line and the word line. In addition, in contrast to a transistor in which a body part is formed in a wide and thick semiconductor substrate, a body part of the vertical transistor, including the channel region, is limited to a very small-sized pillar. As a result, the channel region of the transistor is shortened, which causes short-channel effects such as punch-through or the floating body effect.

Although an ion implantation process for forming a high-density ion region may be performed to solve the above-mentioned problems, the implanted impurities cause an increased electric field and increase the threshold voltage for operation of the cell transistor. As a result, the operational stability of the cell transistor may be deteriorated. In addition, even if a high-density ion implantation is performed, it is very difficult to prevent the occurrence of an electrical short-circuit between a bit line formed at a lower part of a channel region through ion implantation and a word line formed at a sidewall of the channel region.

### BRIEF SUMMARY OF THE INVENTION

Various embodiments of the present invention are directed to providing a semiconductor device and a method for forming the same that substantially obviate one or more problems due to limitations and disadvantages of the related art.

An embodiment of the present invention relates to a semiconductor device and a method for forming the same in which a vertical gate is formed to enclose a sidewall of a pillar with a metal material, a word line overlapping with some parts of the vertical gate is formed as a line structure, and some parts of the pillar are shifted to be coupled to the vertical gate, such that noise caused by a neighboring word line is removed and resistance of the word line is improved, resulting in prevention of transistor deterioration.

In accordance with an aspect of the present invention, a semiconductor device includes: a pillar formed over a semiconductor substrate; a buried bit line formed below the semiconductor substrate; a vertical gate formed to enclose a sidewall of the pillar; an insulation film pattern formed to expose one side of the vertical gate disposed between the pillars; and a word line coupled to the exposed vertical gate.

The buried bit line may be formed of a cobalt silicide (CoSi₂) film.

The buried bit line may be formed below a part disposed between the pillars.

The word line may be formed as a line shape and has a word line structure.

The vertical gate may be formed by burying a laminate structure of a titanium nitride (TiN) or tungsten nitride (WN) film and a tungsten (W) film.

The semiconductor device may further include a body disposed between the buried bit lines.

The body may be formed by burying a polysilicon material.

In accordance with another aspect of the present invention, a method for forming a semiconductor device includes: forming a pillar over a semiconductor substrate; forming a buried bit line below the semiconductor substrate; forming a vertical gate to enclose a sidewall of the pillar; forming an insulation film pattern to expose one side of the vertical gate disposed between the pillars; and forming a word line coupled to the exposed vertical gate.

The buried bit line may be formed of a cobalt silicide (CoSi₂) film.

The vertical gate may be formed by burying a laminate structure of a titanium nitride (TiN) or tungsten nitride (WN) film and a tungsten (W) film.

The method may further include: forming a body between the buried bit lines.

The body may be formed by burying a polysilicon material.

It is to be understood that both the foregoing general description and the following detailed description of the present invention are exemplary and explanatory and are intended to provide further explanation of the invention as claimed.

### BRIEF DESCRIPTION OF THE DRAWINGS

FIGS. 1 to 3 are plan views illustrating a method for forming a semiconductor device having a vertical transistor according to an embodiment of the present invention.

FIGS. 4A to 4G are cross-sectional views of a semiconductor device and illustrate a method for forming a semiconductor device having a vertical transistor according to an embodiment of the present invention.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts.

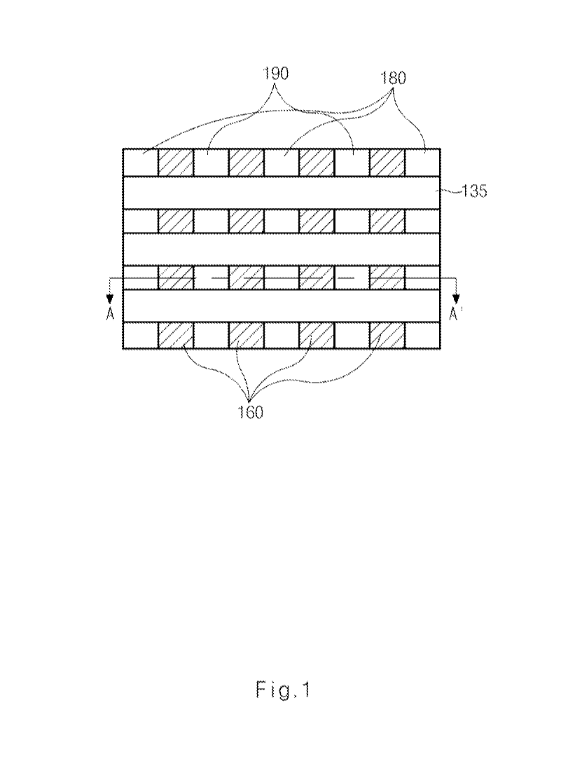

FIGS. 1 to 3 are plan views illustrating a method for forming a semiconductor device having a vertical transistor according to an embodiment of the present invention.

Referring to FIG. 1, the semiconductor device includes a buried bit line 160, a body 180 serving as a semiconductor layer, an insulation film 190, and a gate mask 135.

In an embodiment, after a pillar (not shown) is formed, the buried bit line 160 is formed in a semiconductor substrate. The buried bit line 160 may have a line structure. That is, the buried bit line 160 may be formed as an elongated structure that extends along a line in a given direction.

In an embodiment, the insulation film 190 is disposed between neighboring buried bit lines 160. The insulation film 190 may also be formed to have a line structure. The semiconductor device may further include a body 180 disposed between neighboring buried bit lines 160. The body 180 may be arranged with the insulation film 190 and the bit line 160 in an alternating configuration. For example, in an embodiment, as shown in FIG. 1, moving from left to right with respect to the orientation of the figure, an insulation film 190 may be provided to extend in a line along one sidewall of an adjacent buried bit line 160, and a body 180 may be provided to extend in a line along the other opposing sidewall of the bit line 160.

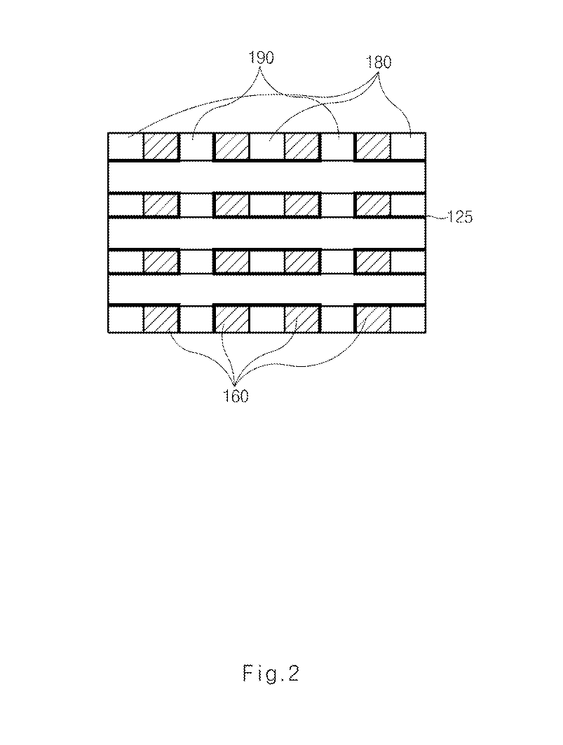

As can be seen from FIG. 2, a vertical gate 125 is formed in a subsequent process using the gate mask 135. The vertical gate 125 may be arranged as a rectangle that encloses a region. The region may include two pillars and a space between the two pillars. A body 180 may be arranged in the space between the pillars. The length of the rectangular region enclosed by the vertical gate 125 may be arranged along a line perpendicular to the buried bit line 160. Preferably, the vertical gate 125 may be formed over sidewalls of the pillar (not shown) provided over the buried bit line 160.

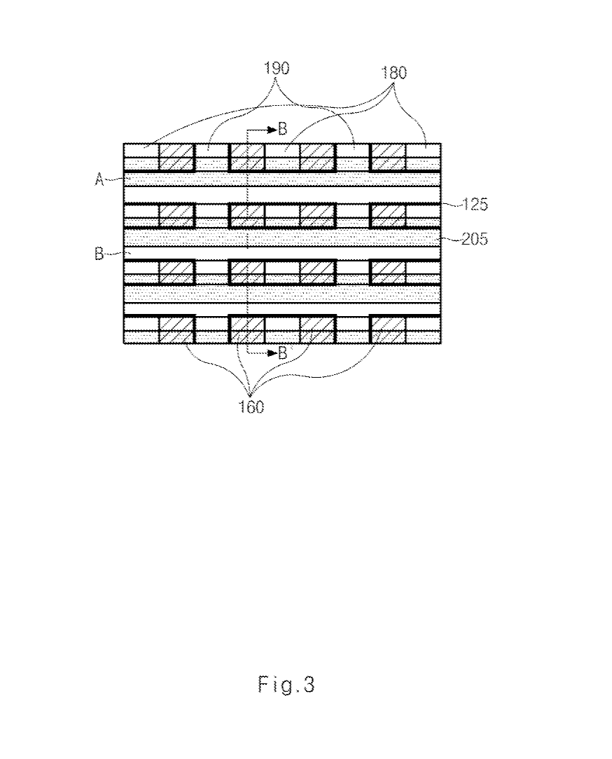

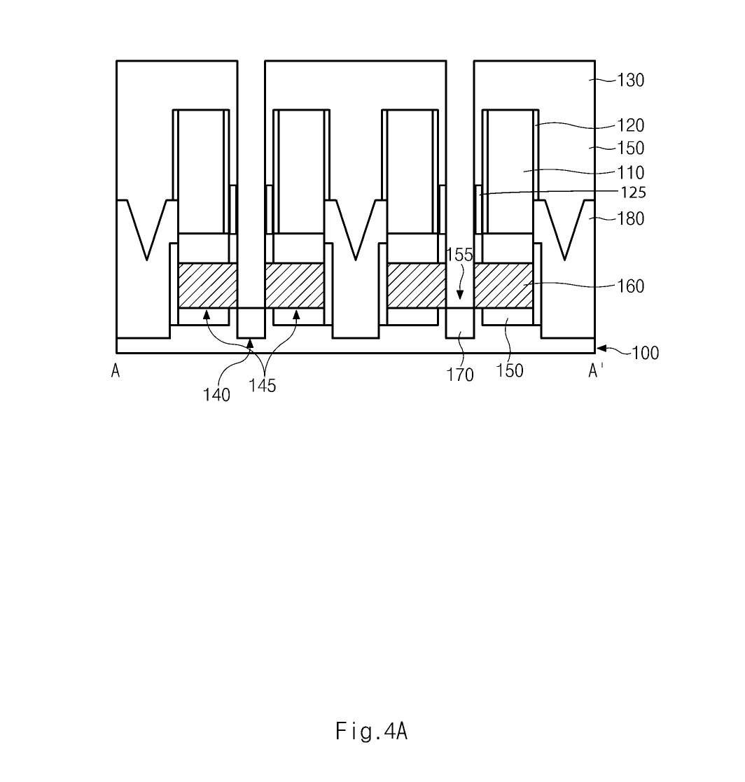

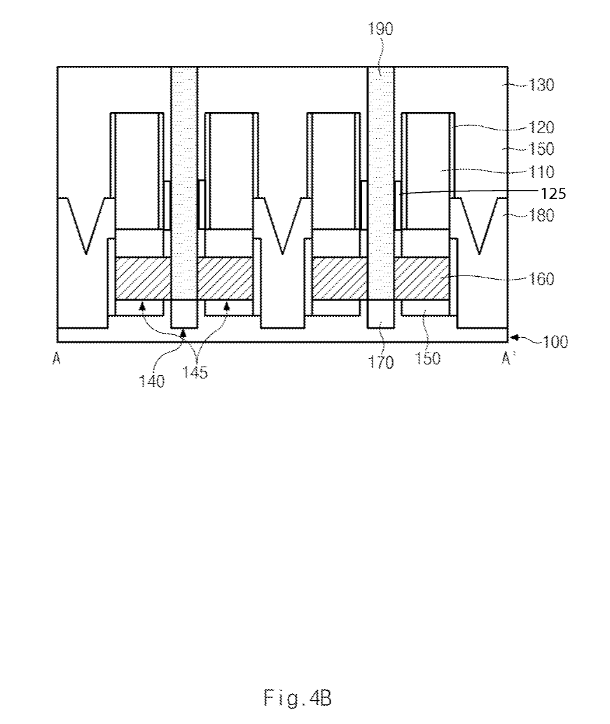

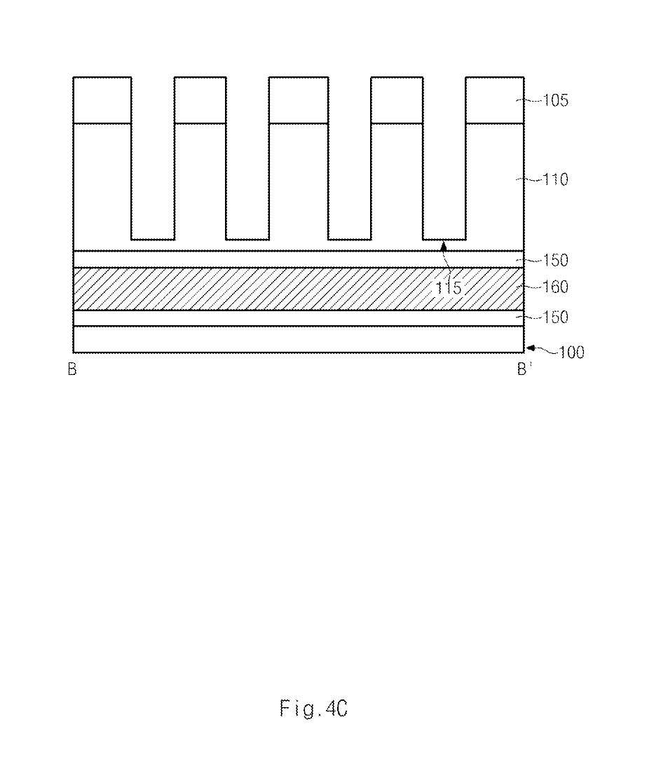

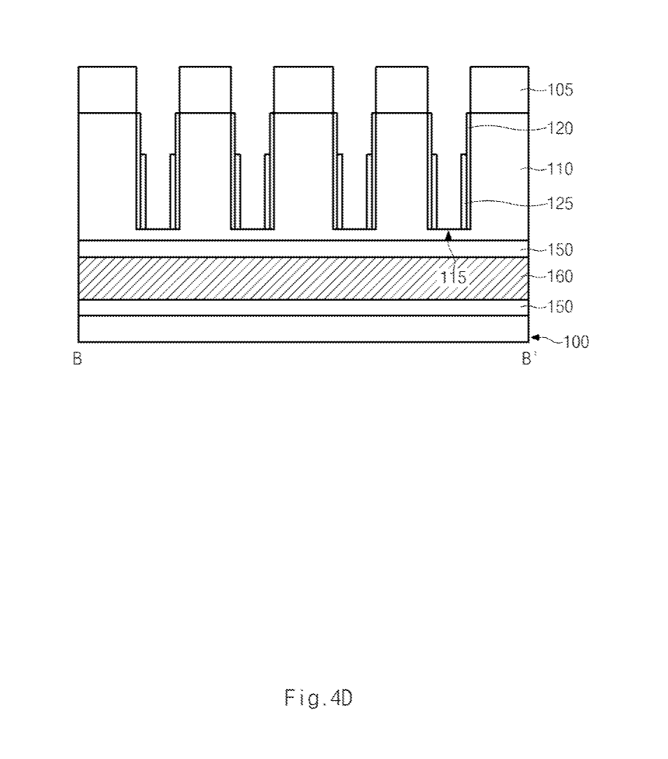

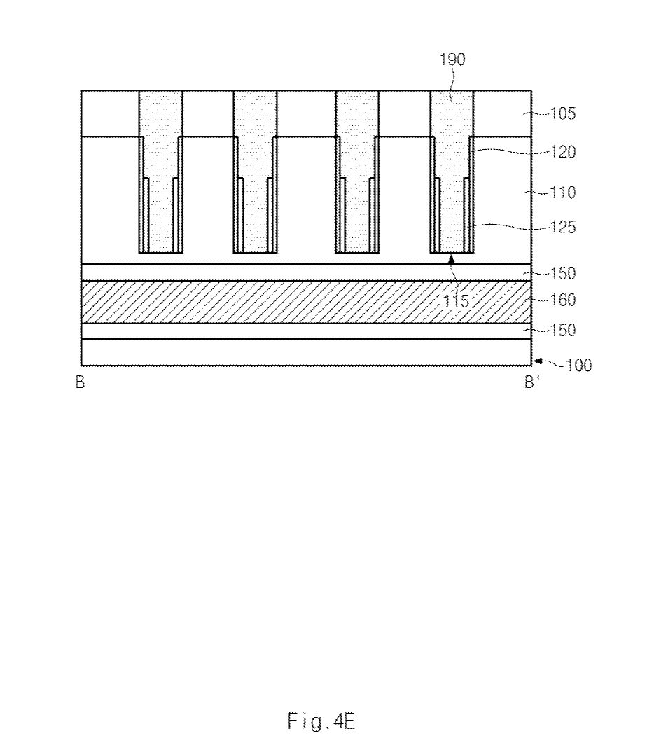

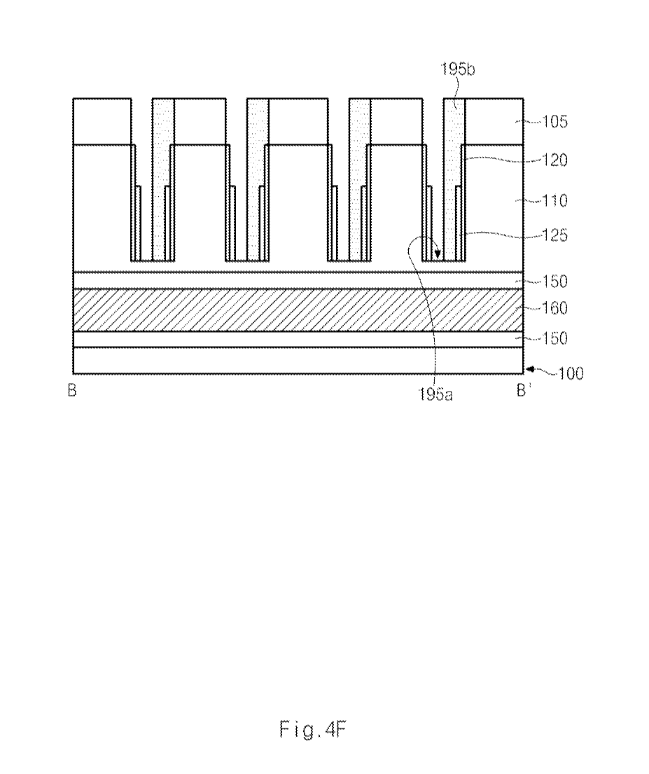

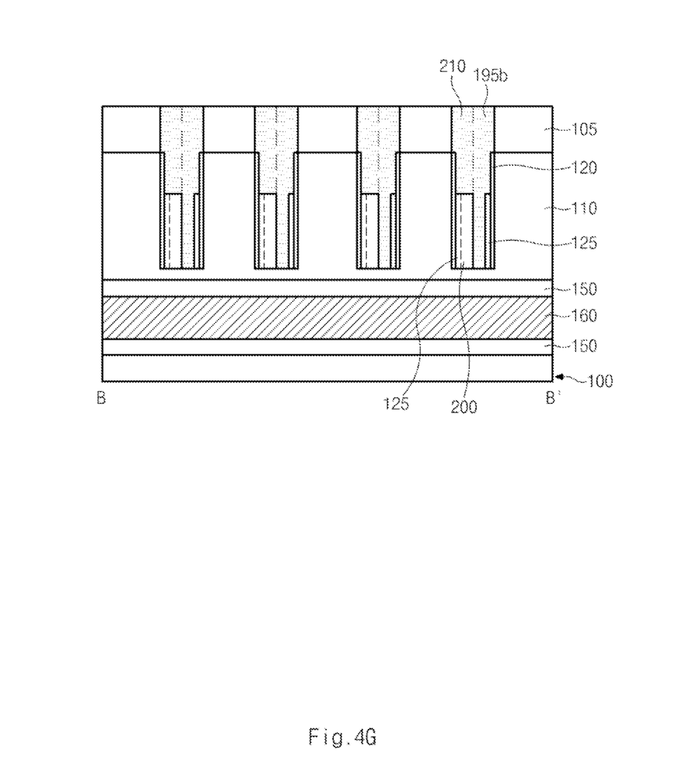

Referring to FIG. 3, an exposure region B of a word line mask 205 crosses the buried bit line 160. In an embodiment, the word line mask 205 is formed to have a line structure and extends along a line that is perpendicular to the buried bit line 160. The exposure region B abuts a sidewall of the vertical gate 125. For example, referring to the exposure region B at the center of FIG. 3, as the exposure region B extends across buried bit lines 160, portions of exposure region B overlap with and thus expose the lower of two opposing sidewalls of the vertical gates 125. A word line 200 (see FIG. 4G) is formed in a subsequent process using the word line mask 205.

FIGS. 4A to 4G are cross-sectional views illustrating a method for forming a semiconductor device having a vertical transistor according to an embodiment of the present invention. FIGS. 4A and 4B are cross-sectional views taken along the line A-A′ of FIG. 1. FIGS. 4C to 4G are cross-sectional views taken along the line B-B′ of FIG. 3.

Referring to FIG. 4A, a mask (not shown) for forming a pillar is formed over the semiconductor substrate 100, and the semiconductor substrate 100 is etched using the mask, forming the pillar 110. A passivation layer 120 is formed over the semiconductor substrate 100 including the pillar 110. The passivation layer 120 may be formed of an insulating material, such as an oxide film or a nitride film. In an embodiment, the passivation layer may be formed on sidewalls of the pillar 110 by physical vapor deposition (PVD). In an embodiment, a portion of the passivation layer 120 may be etched so that the passivation layer 120 remains on both sidewalls of the pillar 110. The passivation layer may be etched by an anisotropic method.

Subsequently, the insulation film 130 is formed over the semiconductor substrate, including the passivation layer 120. In an embodiment, the insulation film 130 is formed of a material that protects the pillar 110 in a subsequent etching process. The insulation film 130 may be formed of, for example, an insulating material such as an oxide or nitride film.

The portion of the insulation film 130 that is disposed between pillars 110 is etched so that a first recess 140 is formed. A bit line 160 will be formed using the first recess 140 in a subsequent process. In an embodiment, during the etching process for forming the first recess 140, a portion of the passivation layer 120 formed over the surface of the semiconductor substrate between pillars 110 is also removed using the semiconductor substrate 100 as an etch target.

Thereafter, a lower part of the first recess 140 is wet-etched, and a bulb-shaped or square-shaped second recess 145 is formed at a lower sidewall of the first recess 140. The second recess 145 extends laterally from the lower portion of the sidewall of the first recess 140 into a lower region of the pillar 110. N-type ions are implanted into the pillar 110 adjacent to the second recess 145, such that a junction 150 (junction region) is formed.

Subsequently, a bit line material is buried in the second recess 145 so that a bit line 160 is formed. The bit line material may include a metal material such as cobalt (Co). In an embodiment, the bit line 160 may be formed by burying a metal material. In another embodiment, the bit line 160 may be formed by implanting ions. In this case, the bit line 160 may be formed of cobalt silicide (CoSi₂).

In addition, a line-type body 180 is formed between two bit lines 160. More specifically, to form the body 180, the insulation film 130 is etched, so that a line-shaped trench is formed and a polysilicon material is buried in the trench. A vertical gate 125 is disposed on sidewalls of neighboring pillars without a body 180 therebetween. As seen in FIG. 3, vertical gate 125 encloses a region including two neighboring pillars 110 with a body 180 between them.

An insulation film 170 is formed in the first recess 140. The insulation film 170 is etched until a sidewall of the bit lines 160 buried in a lower portion of the pillars 110 are exposed to form a third recess 155.

Referring to FIG. 4B, a Silicon On Dielectric (SOD) film is buried in the third recess 155 to form insulation film 190.

Referring to FIG. 4C, the hard mask layer 105 is formed over the semiconductor substrate 100 including the buried bit line 160. After a photoresist film is formed over the hard mask layer 105, a photoresist pattern is formed by an exposure and development process using the gate mask 135 (see FIG. 1). The hard mask layer 105 and the semiconductor substrate 100 are etched using the photoresist pattern as an etch mask, so that a hole 115 defining the pillar 110 is formed.

Referring to FIG. 4D, a passivation layer 120 is formed over a sidewall of the hole 115. Then, a gate material is deposited over the entire surface of the resulting structure, including an upper part of the passivation layer 120. The gate material and the passivation layer 120 are etched until they remain only over sidewalls of the hole 115. The gate material may be etched further using an additional etching process. A height of the gate material may be lower than a height of the passivation layer 120. Thus, the remaining gate material forms the gate 125, which is provided over the remaining passivation layer 120 on sidewalls of the pillar 110. In an embodiment, the gate material is titanium nitride (TiN).

In other embodiments, the gate material may be a laminate structure of a tungsten nitride (WN) film and a tungsten (W) film.

Referring to FIG. 4E, an insulating material, for example a spin on dielectric (SOD) material, is deposited in the hole 115. The SOD material is then planarized (CMP-processed) until the hard mask layer 105 is exposed to form the insulation layer 190.

Referring to FIG. 4F, the insulation layer 190 is etched using a line-shaped word line mask 205 (see FIG. 3) as an etch mask, so that a recess 195a and an SOD pattern 195b is formed.

Referring to FIG. 4G, a TiN film is deposited in the recess 195a, and is then etched back until it remains in a lower portion of the recess 195a, resulting in formation of the word line 200. As a result, a portion of the vertical gate 125 is contiguous with a portion of the word line 200.

Subsequently, an SOD material 210 is formed in an upper part of the recess 195a over the word line 200 and over the passivation layer 120.

As is apparent from the above description, in a semiconductor device and a method for forming the same according to an embodiment of the present invention, a vertical gate 125 comprising a metal material is formed to enclose a region including two adjacent pillars 110, and a word line is formed to overlap with a portion of the vertical gate. In an embodiment, the word line is merged, or contiguous, with a portion of the vertical gate. In an embodiment, the vertical gate is disposed on four sides of an enclosed region which includes two pillars separated by a body portion, and a portion of the vertical gate disposed on one side of the enclosed region is contiguous with a word line running along that side. In other words, a portion of the vertical gate 125 is integrated with a portion of the word line 200. As a result, noise caused by a neighboring word line can be reduced and resistance of the word line is improved, thus preventing deterioration of the operational stability of the transistor.

Those skilled in the art will appreciate that the present invention may be carried out in other specific ways than those set forth herein without departing from the spirit and essential characteristics of the present invention. The above embodiments are therefore to be construed in all aspects as illustrative and not restrictive. The scope of the invention should be determined by the appended claims and their legal equivalents, not by the above descriptions. All variations coming within the meaning and equivalency range of the appended claims are intended to be embraced therein.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a first pillar formed over a semiconductor substrate;
a buried bit line formed in a lower portion of the first pillar;
a vertical gate formed over a sidewall of the first pillar; and
a word line contiguous with a portion of the vertical gate.

2. The semiconductor device according to claim 1, wherein the buried bit line includes a cobalt silicide (CoSi₂) film.

3. The semiconductor device according to claim 1, wherein the buried bit line is disposed below the vertical gate.

4. The semiconductor device according to claim 1, wherein the word line has a line shape.

5. The semiconductor device according to claim 1, wherein the vertical gate comprises a laminate structure of a titanium nitride (TiN) or tungsten nitride (WN) film, and a tungsten (W) film.

6. The semiconductor device according to claim 1, further comprising:
a body disposed between the bit line and an adjacent bit line.

7. The semiconductor device according to claim 6, wherein the body comprises a polysilicon material.

8. The semiconductor device of claim 1, further comprising:
a second pillar neighboring the first pillar; and
an insulation film disposed between the portion of the vertical gate that is contiguous with the word line and the second pillar,
wherein the buried bit line runs through lower portions of the first and second pillars.

9. The semiconductor device of claim 1, further comprising:
a third pillar neighboring the first pillar; and
a body structure disposed between the first and third pillars,
wherein the vertical gate is arranged over sidewalls of the first and third pillars to enclose a region that includes the first pillar, the third pillar, and the body structure.

10. The semiconductor device of claim 9, wherein the enclosed region has a length that is perpendicular to a length of the buried bit line.
